(19) United States
(12) Patent Application Publication
(10) Pub. No.: US 2017/0199253 A1
(43) Pub. Date: Jul. 13, 2017

(54) MAGNETIC SENSOR DEVICE AND METHOD OF MANUFACTURE THEREOF

(71) Applicant: Mitsubishi Electric Corporation, Chiyoda-ku, Tokyo (JP)

(72) Inventors: Masaaki OKADA, Chiyoda-ku (JP); Hideki MATSUI, Chiyoda-ku (JP); Tomokazu OGOMI, Chiyoda-ku (JP); Sadaaki YOSHIOKA, Chiyoda-ku (JP)

(73) Assignee: Mitsubishi Electric Corporation, Chiyoda-ku, Tokyo (JP)

(21) Appl. No.: 15/313,398

(22) PCT Filed: Jul. 13, 2015
(86) PCT No.: PCT/JP2015/070035

§ 371 Date: Nov. 22, 2016

(30) Foreign Application Priority Data
Jul. 25, 2014 (JP) 2014-151844

(51) Int. Cl. G01R 33/09; G07D 7/04; H01L 43/08; G01R 33/00

(52) U.S. Cl. CPC G01R 33/09; G01R 33/0017; G01R 33/0052; G07D 7/04; H01L 43/08

(57) ABSTRACT

A magnetic sensor device including: a board mounted with a magnetoresistive effect element, a magnet to form a bias magnetic field for the magnetoresistive effect element, an enclosure having an opening on a side of a conveyance path where a to-be-detected object is conveyed, also including a housing portion to house the magnet and the board, and a cover to cover a surface on a side of the opening of the housing portion. The enclosure includes step portions on which the board is supported such that the board lies across the opening and extends parallel to the conveyance path, and grooves, continuous with the step portions, extending from the opening to an outer surface of the enclosure on a side of the conveyance direction.

### TECHNICAL FIELD

The present disclosure relates to a magnetic sensor device that detects a magnetic pattern printed on paper currency and the like and relates to a manufacturing method thereof.

### BACKGROUND ART

Magnetic sensor devices that detect magnetic patterns printed on paper currency are used for determining the authenticity of paper currency and the like. A magnetic sensor device includes a magnetoresistive effect element, a magnet to apply a bias magnetic field for the magnetoresistive effect element, an enclosure to support the magnetoresistive effect element and the magnet, and a cover to protect the magnetoresistive effect element. The magnet and the magnetoresistive effect element are fixed to the enclosure of the magnetic sensor device and are covered by the cover.

Patent Literature 1 discloses a metal cover that is formed through a simple process and discloses a magnetic sensor structure in which the metal cover and a body can be fixed easily so as not to come apart from each other. In the magnetic sensor of Patent Literature 1, the metal cover is fixed to the insulation casing by coupling a metal-cover-side coupling part provided on the metal cover together with an insulation-casing-side coupling part provided on the insulation casing.

In the magnetic sensor in Patent Literature 2 claw-portion engaging grooves are provided in the side surfaces of the casing, and cover fixing claw portions to be engaged with the claw-portion engaging grooves are provided for the cover. The claw-portion engaging grooves are each provided with protrusions that protrude into the claw-portion engaging groove, and notches are provided for the cover. At the time of sliding the cover to a predetermined location with respect to the casing, the notches are engaged with the protrusions to position and fix both the casing and the cover.

### CITATION LIST

### Patent Literature

Patent Literature 1: Unexamined Japanese Patent Application Kokai Publication No. H11-66517

Patent Literature 2: Unexamined Japanese Patent Application Kokai Publication No. 2001-59860

### SUMMARY OF INVENTION

### Technical Problem

The magnetic sensors in Patent Literature 1 and Patent Literature 2 each have a structure in which an engaging piece provided on the metal cover is used to fix the metal cover to the insulation casing for the fixing of the body of the magnetic sensor and the metal cover together. These magnetic sensors are intended for the specific purpose of fixing a metal cover to a casing without a sealing resin for fixing, which was once necessary. The magnetic sensors in Patent Literature 1 and Patent Literature 2 do not seal a magnetoresistive effect element.

In the case of fixedly attaching a metal cover and a board mounted with a magnetoresistive effect element to an enclosure, that is, fixedly attaching two independent articles to the enclosure, there was an issue of having to divide the fixing job into two tasks because, for example, the enclosure and the board first had to be fixedly attached together before the metal cover could be fixed to the enclosure fixedly attached with the board.

The present disclosure has been made in view of the foregoing, and an object of the present disclosure is to fixedly attach at the same time to an enclosure of a magnetic sensor device, a magnetoresistive effect element-mounted board and a cover for protecting the magnetoresistive effect element.

### Solution to Problem

In order to achieve the aforementioned object, a magnetic sensor device of the present disclosure includes a board mounted with a magnetoresistive effect element, a magnet to form a bias magnetic field for the magnetoresistive effect element, an enclosure having an opening on a side of a conveyance path where a to-be-detected object containing a magnetic component is conveyed, and housing the magnet and the board with the magnetoresistive effect element being disposed on the side of the conveyance path, and a cover to cover a plane on a side of the opening of the enclosure. The enclosure includes step portions on which the board is supported in such a manner that the board lies across the opening on the side of the conveyance path and extends along a conveyance direction of the to-be-detected object, and includes grooves, continuous with the step portions, extending from the opening to an outer surface of the enclosure on a side of the conveyance direction.

A magnetic sensor device manufacturing method of the present disclosure includes an adhesive application step for applying an adhesive onto step portions and grooves of an enclosure, wherein (i) the enclosure has an opening on a side of a conveyance path where a to-be-detected object containing a magnetic component is conveyed and the enclosure houses (ia) a board mounted with a magnetoresistive effect element disposed on the side of the conveyance path and (ib) a magnet to form a bias magnetic field for the magnetoresistive effect element, (ii) the step portions support a board in such a manner that the board lies across the opening on the side of the conveyance path and extends along a conveyance direction of the to-be-detected object, and (iii) the grooves, continuous with the step portions, extend from the opening to an outer surface of the enclosure on a side of the conveyance direction, a board placement step for placing the board on the step portions such that the board lies across the opening and extends along the conveyance direction of the to-be-detected object, a cover placement step for placing a cover on a surface of the opening of the enclosure so as to cover the surface of the opening side of the enclosure, and an adhesive curing step for curing the adhesive after the board placement step and the cover placement step.

### Advantageous Effects of Invention

The magnetic sensor device and the manufacturing method thereof enable the cover for protecting the magnetoresistive effect element and the board mounted with the magnetoresistive effect element to be fixedly attached to the enclosure at the same time because (i) the step portions formed at the opening to support the board that is laid along the conveyance direction of the to-be-detected object, and (ii) the grooves, continuous with the step portions, extending from the opening to the outer surface of the enclosure on a side of the conveyance direction are provided.

### BRIEF DESCRIPTION OF DRAWINGS

FIG. 1 is a cross-sectional view of a basic structure of a magnetic sensor device as viewed in a main scanning direction;

FIG. 2 is a cross-sectional view of the magnetic sensor device of Embodiment 1 of the present disclosure as viewed in the main scanning direction;

FIG. 3 is an enlarged cross-sectional view of an attached section illustrated in FIG. 2;

FIG. 4 is a perspective view of an enclosure of Embodiment 1;

FIG. 5 is an exploded cross-sectional view of the magnetic sensor device of Embodiment 1;

FIG. 6 is a cross-sectional view illustrating a state in which an adhesive is applied to the enclosure of the magnetic sensor device of Embodiment 1;

FIG. 7 is a cross-sectional view illustrating a state in which a board is placed on step portions;

FIG. 8 is a cross-sectional view illustrating a state in which a cover is placed on the enclosure;

FIG. 9 is a cross-sectional view of a magnetic sensor device of Embodiment 2 of the present disclosure as viewed in a main scanning direction; and

FIG. 10 is a cross-sectional view of a magnetic sensor device of Embodiment 3 of the present disclosure as viewed in a main scanning direction.

### DESCRIPTION OF EMBODIMENTS

Hereinafter, the embodiments of the present disclosure are described in detail with reference to the drawings. In the drawings, the same or corresponding portions are marked with the same reference signs.

### Embodiment 1

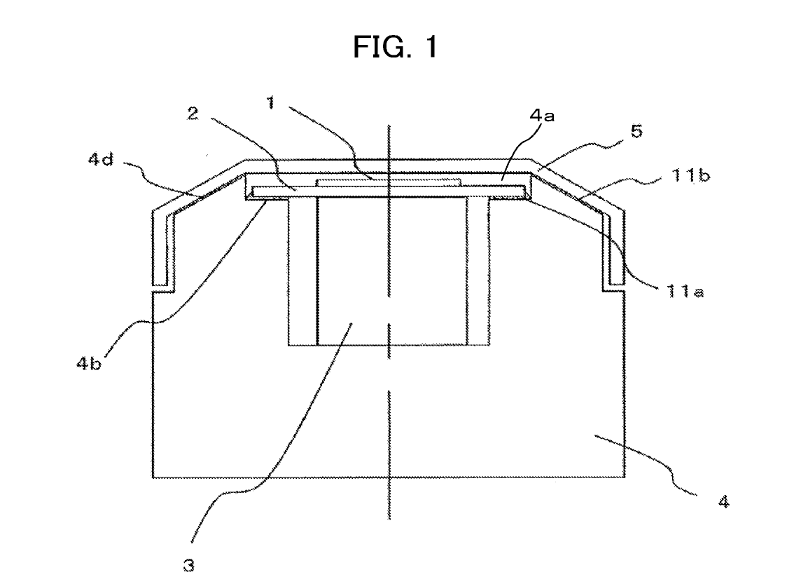

FIG. 1 is a cross-sectional view of a basic structure of a magnetic sensor device as viewed in a main scanning direction. The magnetic sensor device includes an enclosure 4, a board 2 that includes a metal carrier mounted with a magnetoresistive effect element 1, and a cover 5 for protecting the magnetoresistive effect element 1. The board 2 is attached to step portions 4b formed in an opening 4a of the enclosure 4 with an adhesive 11a. The cover 5 is attached to opening outer edges 4d of the enclosure with an adhesive 11b.

To fixedly attach the board 2 and the cover 5 to the enclosure 4, the adhesive 11a applied and spread on the step portions 4b, the opening outer edges 4d, and grooves 4c of the enclosure 4 to which the board 2 is attached, causes the board 2 to fixedly attach to the step portions 4b of the enclosure 4. Next, the cover 5 fixedly attaches to the opening outer edges 4d of the enclosure 4. The thickness of the adhesive 11 is greater than the space between the cover 5 and the opening outer edges 4d of the enclosure 4, but the cover 5 and the grooves 4c of the enclosure 4 are fixedly attached together. The magnetic sensor device in FIG. 1 undergoes a two-step process, that is, a step for attaching the board 2 to the enclosure 4 and a step for attaching the cover 5 to the enclosure 4.

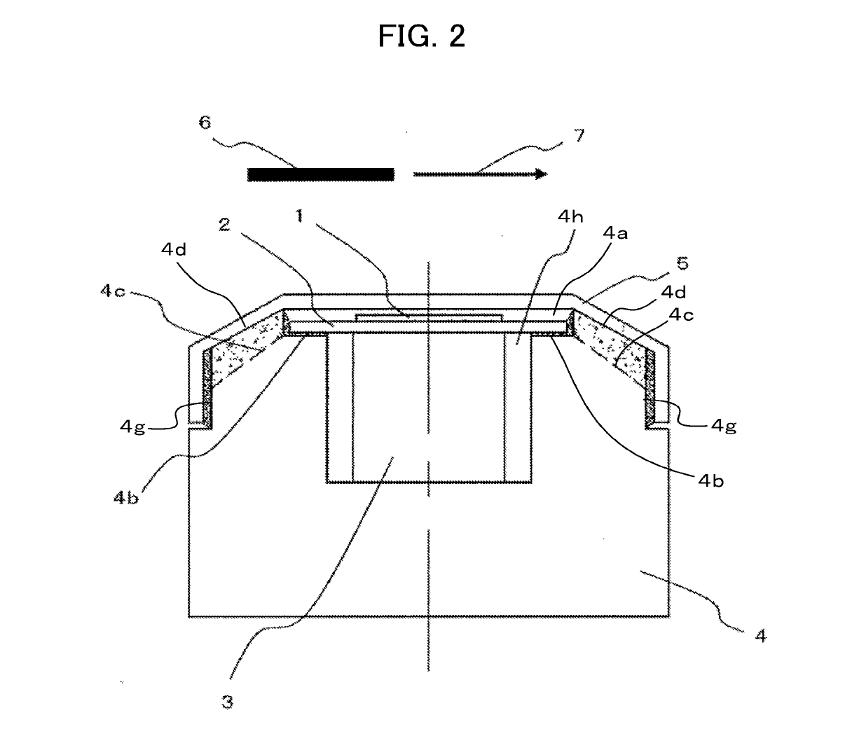

FIG. 2 is a cross-sectional view of the magnetic sensor device of Embodiment 1 of the present disclosure as viewed in the main scanning direction. A to-be-detected object 6 such as paper currency containing a magnetic component is conveyed along a conveyance direction 7 on a side of the cover 5 of the magnetic sensor device. The magnetic sensor device includes the magnetoresistive effect element 1, the board 2 mounted with the magnetoresistive effect element 1, a magnet 3 to form a bias magnetic field for the magnetoresistive effect element 1, the enclosure 4 to house and support the board 2 and the magnet 3, and the cover 5 to cover the magnetoresistive effect element 1 and to be fixed to the enclosure 4.

The magnet 3 forms a magnetic field in a space which the conveyance path crosses. The magnetic sensor device detects changes in the magnetic field caused by the magnetic component of the to-be-detected object 6 and detects a magnetic pattern of the to-be-detected object 6. The magnetoresistive effect element 1 is disposed on the board 2 so as to extend in a direction orthogonal to a paper surface in FIG. 2. The direction in which this magnetoresistive effect element 1 is arranged is referred to as the main scanning direction. Typically, the main scanning direction is a direction that is parallel to a surface along the conveyance path of the to-be-detected object 6 and is orthogonal to the conveyance direction 7.

Although there is no single set way to dispose the magnetic poles of the magnet 3, magnetic lines of force that extend from one of the poles of the magnet 3 interlink with the conveyance path along which the to-be-detected object 6 is conveyed and then enter the other magnetic pole. The cover 5 is non-magnetic, thereby enabling the magnetic lines of force of the magnet 3 to unaffectedly pass through the cover 5. The magnetoresistive effect element 1 is disposed within the magnetic field of the magnet 3 and the magnet 3 forms a bias magnetic field for the magnetoresistive effect element 1.

The enclosure 4 has a housing portion 4h to house the board 2 and the magnet 3. The housing portion 4h has an opening 4a on the side of the conveyance path. The enclosure 4 has the opening 4a on the side of the conveyance path, and the magnet 3 is inserted and housed in the housing portion 4h via the opening 4a. The housing portion 4h includes step portions 4b where the board 2 is supported at opposite sides thereof on the step portions 4b in such a manner that the board 2 lies on the side of the opening 4a facing the conveyance path. In the housing portion 4h illustrated in FIG. 2, the magnet 3 is depicted as being inserted into the housing portion 4h via the opening 4a. Of course, a bottom opening may be provided on a bottom portion of the enclosure 4, which is a side opposite to the conveyance path of the enclosure 4, and the magnet 3 may be inserted and housed in the housing portion 4h via the bottom opening. In such a case, the fixing of the magnet 3 may conceivably be conducted with use of a method in which the magnet 3 is fixed by a sealing member to seal the bottom opening. Also, a side opening may be formed on a side of the enclosure 4 so that the housing portion 4h communicates with an edge portion of the enclosure 4 in the main scanning direction, and the magnet 3 may be housed in the housing portion 4h by inserting the magnet 3 into the side opening in the main scanning direction.

The opening outer edges 4d of the enclosure 4 that come in contact with the cover 5 on a side of the conveyance path slant away from the conveyance path, as the opening outer edges 4d approach the outer surface (side walls 4g) in the conveyance direction from the opening 4a. The opening outer edges 4d slanted in this manner are continuous with the side walls 4g extending in the main scanning direction of the enclosure 4. The grooves 4c of the enclosure 4 likewise are slanted away from the conveyance path, as the grooves 4c approach the outer surface in the conveyance direction from the opening 4a. The grooves 4c slanted in this manner are connected to the side walls 4g extending in the main scanning direction of the enclosure 4. In other words, the opening outer edges 4d and the grooves 4c reside between the opening 4a and each of the side walls 4g and extend in the main scanning direction. Specifically, the opening outer edges 4d and the grooves 4c may be regarded as being alternatingly arranged along the main scanning direction. Also, the grooves 4c may be regarded as indentations along the conveyance direction 7 formed on the opening outer edges 4d formed along the main scanning direction. Further, the opening outer edges 4d may be regarded as being formed along the main scanning direction and may also be regarded as being protrusions formed along the conveyance direction 7. The grooves 4c are formed between these protrusions. The cover 5 is formed so as to align with the opening outer edges 4d of the enclosure 4. The board 2 and the cover 5 are fixed to the enclosure with the adhesive 11. The adhesive 11 is also interposed between the cover 5 and the grooves 4c.

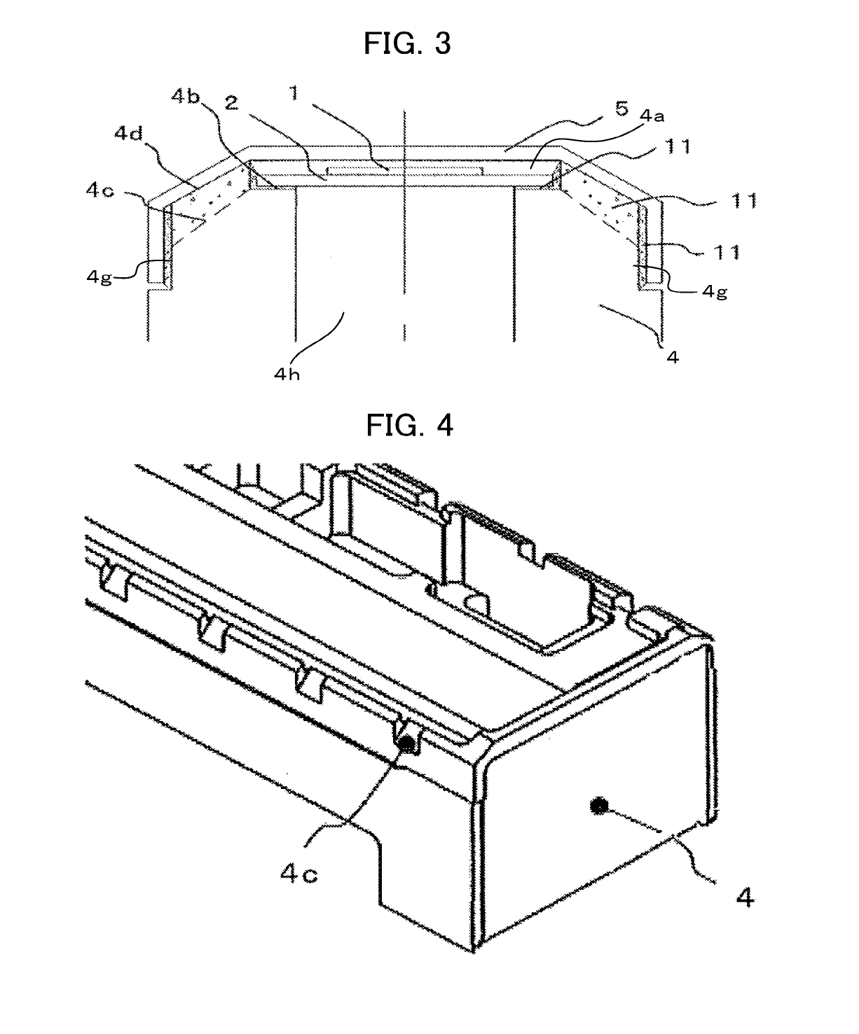

FIG. 3 is an enlarged cross-sectional view of an attached section illustrated in FIG. 2. The enclosure 4 has formed the grooves 4c, continuous with the step portions 4b, extending from the opening 4a to the outer surface on the side of the conveyance direction. Specifically, the step portions 4b and the grooves 4c are continuous in the conveyance direction 7. The area of the step portions 4b and the grooves 4c connecting with each other may be equal in height or the grooves 4c may be higher than the step portions 4b. However, when the grooves 4c are higher than the step portions 4b, the grooves 4c should be high enough so that any adhesive 11 thrusted out from the step portions 4b when the board 2 is placed on the step portions 4b streams into the grooves 4c. The grooves 4c slant away from the conveyance path, as the grooves 4c approach the outer surface in the conveyance direction from the opening 4a. The board 2 is attached to the step portions 4b with the adhesive 11. When the board 2 is placed on the step portions 4b, an excess portion of the adhesive 11 that is thrusted out from the step portions 4b enters into the grooves 4c. That is, the grooves 4c serve as an adhesive reservoir for the adhesive 11. The adhesive 11 is also applied to the grooves 4c in advance. Therefore, when the cover 5 is fixed to the enclosure 4, the excess portion of the adhesive 11 on the step portions 4b, and the pre-applied adhesive 11 are present between the grooves 4c and the cover 5. Although the adhesive 11 is applied to fill the grooves 4c in advance, when determining the application amount, it is important to take into account the excess portion of the adhesive 11 that gets thrusted out from the step portions 4b. The cover 5 is fixedly attached to the enclosure 4 with the adhesive 11 on the slanted surfaces and the outer surface on the side of the conveyance direction. When the adhesive 11 remains on a continuous portion of the step portions 4b and the grooves 4c, the adhesive 11 for fixing the board 2 and the adhesive 11 for fixing the cover 5 are connected via the adhesive 11 in the grooves 4c. The adhesive 11 for fixing the cover 5 and the opening outer edges 4d and the adhesive 11 for fixing the cover 5 and the grooves 4c are continuous.

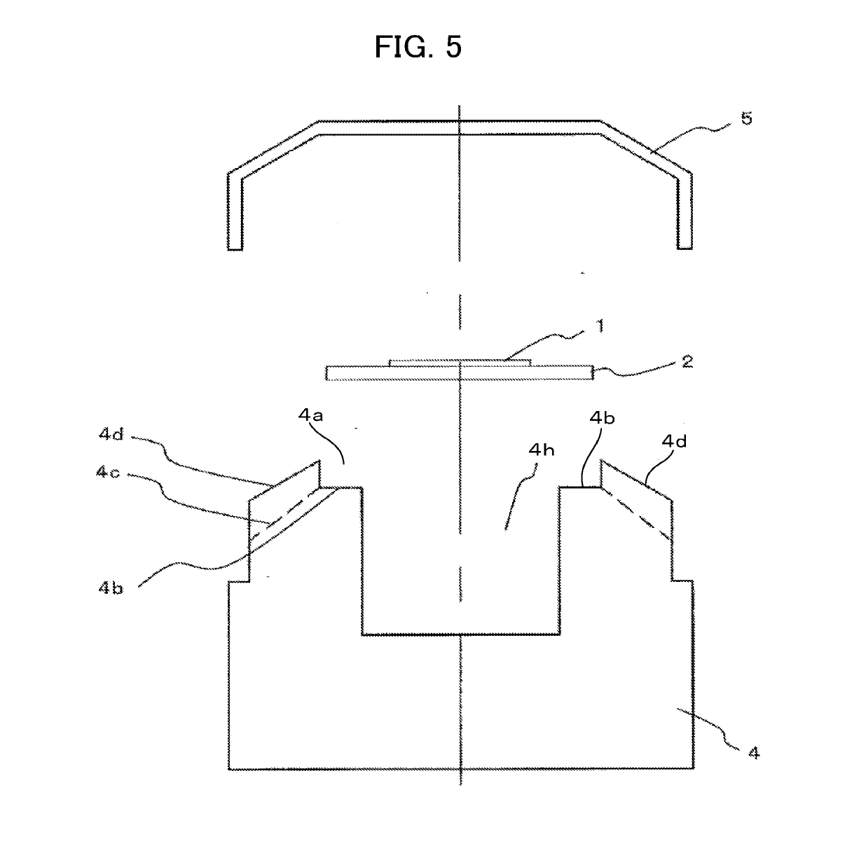

FIG. 4 is a perspective view of an enclosure of Embodiment 1. The enclosure 4 has the grooves 4c extending from the opening 4a to the outer surface on the side of the conveyance direction in multiple locations along the main scanning direction. Next, a method of manufacturing the magnetic sensor device of Embodiment 1 is described with reference to FIGS. 5 to 8.

FIG. 5 is an exploded cross-sectional view of the magnetic sensor device of Embodiment 1. In FIG. 5, the magnet 3 is omitted. In the case of applying an adhesive to fix the board 2 and the cover 5 to the enclosure 4, the adhesive 11 is applied to the step portions 4b so that the adhesive 11 fills up the grooves 4c. After application of the adhesive 11 the board 2 is placed on the step portions 4b. Thereafter, the cover 5 is placed on the opening outer edges 4d, force is applied thereto, and then the adhesive is cured.

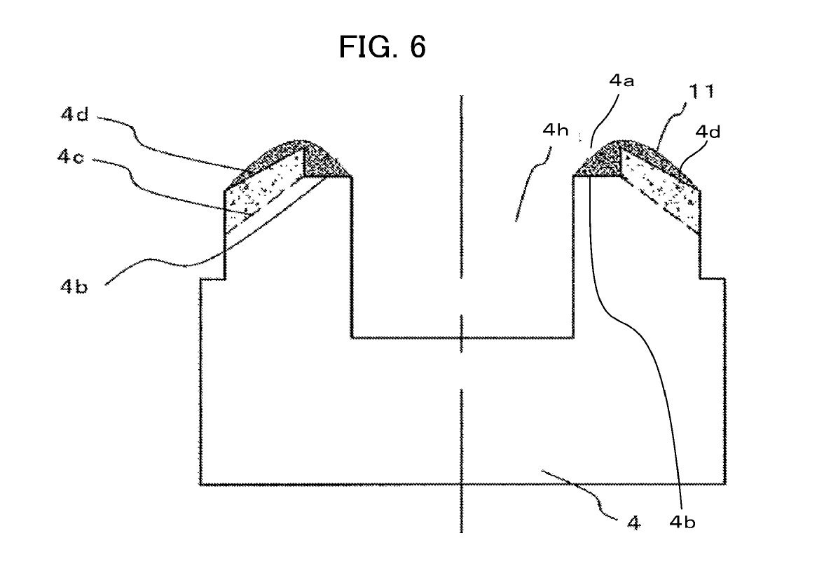

FIG. 6 is a cross-sectional view illustrating a state in which an adhesive is applied to the enclosure of the magnetic sensor device of Embodiment 1. The adhesive 11 is applied to the step portions 4b and the opening outer edges 4d of the enclosure 4 on both front and rear sides in the conveyance direction. As this point in time, the adhesive 11 is applied in such a manner that the grooves 4c serving as the adhesive reservoir are also filled with the adhesive 11. The application amount applied to the grooves 4c is as described above. In FIG. 6, although the magnet 3 is omitted, when the adhesive 11 is applied to the step portions 4b and the opening outer edges 4d and the board 2 is placed down, the magnet 3 is already housed in and fixed to the housing portion 4h. At the very least, when the board 2 is fixed to the step portions 4b with the adhesive 11, the magnet 3 and the board 2 are already in contact with each other.

Bringing the magnet 3 into contact with the board 2 mitigates warpage or bending of the board 2. Also, the bringing of the magnet 3 into contact with the board 2 enables the magnet 3 to function as a heat sink for dissipating heat generated from the magnetoresistive effect element 1, circuit elements of the board 3, and the like. The reason is that the fixing of the board 2 to the step portions 4b so as to bridge the step portions 4b that are facing the conveyance direction 7 easily widens the contact area between the board 2 and the magnet 3. This also inhibits the excess portion of the adhesive 11 that is thrusted from the step portions 4b from flowing into the magnet 3 side. Accordingly, the length of the magnet 3 in the conveyance direction 7 can be increased, thereby enabling even easier widening of the contact area between the board 2 and the magnet 3. When the magnet 3 is made to function as a heat sink, a heat dissipation member having high heat conductivity such as a bus bar may be situated thermally-adjacent to the magnet 3, so that heat from the magnet 3 dissipates to outside of the enclosure 4. To further increase the conductivity of heat from the board 2 to the magnet 3, a heat conducting member such as a heat-conductive sheet or a heat-conductive gel may be sandwiched between the board 2 and the magnet 3.

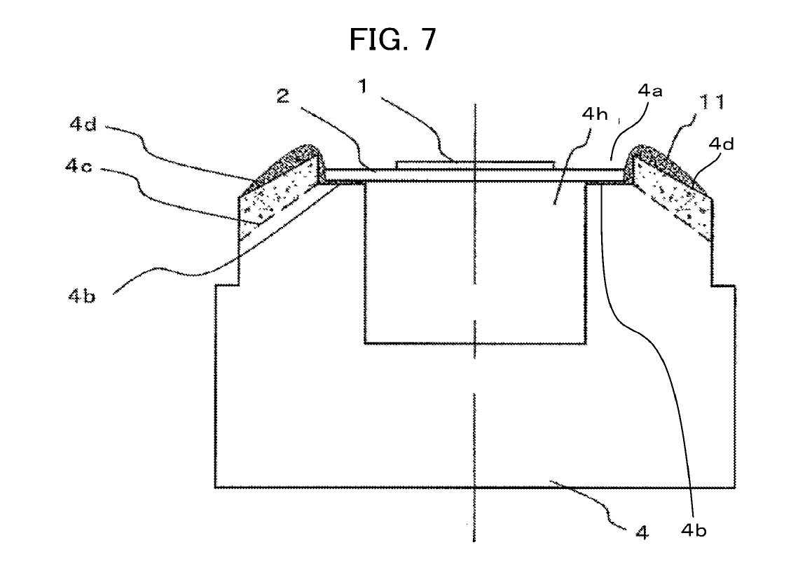

FIG. 7 is a cross-sectional view illustrating a state in which a board is placed on step portions. The magnet 3 is omitted in FIG. 7 as well. The board 2 is placed on the step portions 4b so as to bridge the step portions 4b that are facing the conveyance direction 7 of the to-be-detected object 6. When the board 2 is applied with pressure to the step portions 4b, a portion of the adhesive 11 applied to the step portions 4b flows into the grooves 4c which serve as the adhesive reservoir. The excess portion of the adhesive 11 that flowed into the grooves 4c combined with the adhesive 11 that was applied in advance to the grooves 4c adequately fills the grooves 4c with the adhesive 11. The opening outer edges 4d and the grooves 4c of the enclosure 4 to which the cover 5 on the side of the conveyance path comes in contact slant away from the conveyance path, as the opening outer edges 4d and the grooves 4c approach the outer surface on the side of the conveyance direction from the opening 4a, and thus the adhesive 11 of the opening outer edges 4d and the grooves 4c coats evenly over the opening outer edges 4d and the grooves 4c without accumulating in a single location.

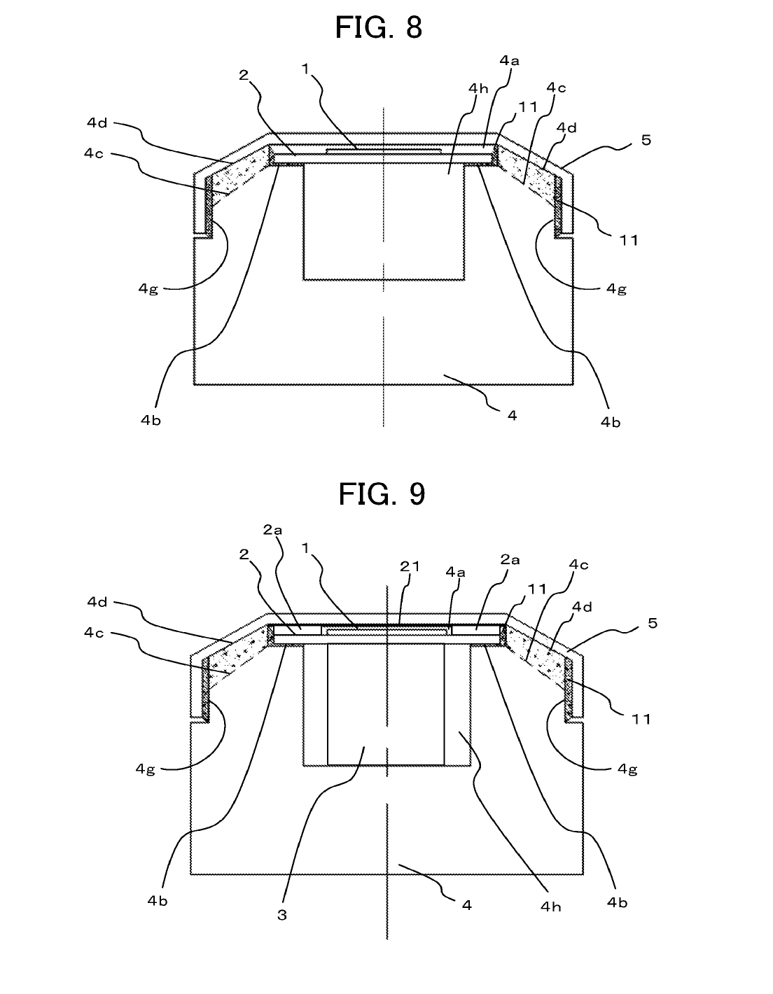

FIG. 8 is a cross-sectional view illustrating a state in which a cover is placed on the enclosure. When the cover 5 is placed on the opening outer edges 4d of the enclosure 4 where the grooves 4c serving as the adhesive reservoir are formed, the adhesive 11 applied to the opening outer edges 4d causes the cover 5 to attach to the opening outer edges 4d. At this time, the excess portion of the adhesive 11 that is applied to the outer edges 4d flows into the grooves 4c serving as the adhesive reservoir, and also spills over the side walls 4g that extend in the main scanning direction of the enclosure 4. Naturally, the excess portion of the adhesive 11 thrusted from the step portions 4b when the board 2 is placed may spill over the side walls 4g. The adhesive 11 that spills over the side walls 4g causes the cover 5 to attach to the side walls 4g. Furthermore, the adhesive 11 filling the grooves 4c serving as the adhesive reservoir causes the cover 5 to attach to the grooves 4c serving as the adhesive reservoir. In this way, the cover 5 is attached to enclosure 4. At this point, since the board 2 and the cover 5 are each temporarily fixed together to the enclosure 4 with the adhesive 11, the board 2 and the cover 5 are then each fixed to the enclosure 4 by, for example, thermal curing the adhesive 11.

On the magnetic sensor device illustrated in FIG. 1, for example, the board 2 is fixedly attached to the enclosure 4 by thermal curing or the like, and then the cover 5 is fixedly attached by thermal curing or the like. In contrast, on the magnetic sensor device of Embodiment 1, the board 2 and the cover 5 are temporarily fixed to the enclosure 4, and then the board 2 and the cover 5 are fixed to the enclosure 4 by thermal curing or the like. That is, the board 2 and the cover 5 are fixedly attached at the same time. Here, the wording “same time” means that the application of the adhesive and the work hardening are each performed once. As a result, a curing step such as thermal curing can be omitted thereby simplifying the manufacturing process. Since the heating step only needs to be performed once, the magnetoresistive effect element 1 is subjected to less heat stress, thereby improving reliability of the magnetic sensor device. Also, the adhesive 11 that oozes out when the board 2 is placed on the step portions 4b to form a bridge thereover subsequently flows into the grooves 4c serving as the adhesive reservoir, and this obviates the need to perform a task of adhesive removal, thereby reducing the burden of work. Likewise, the adhesive 11 that oozes out when the cover 5 is placed on the opening outer edges 4d subsequently flows into the grooves 4c serving as the adhesive reservoir, and this obviates the need to perform the adhesive removal task, thereby reducing the burden of work.

### Embodiment 2

FIG. 9 is a cross-sectional view of a magnetic sensor device of Embodiment 2 of the present disclosure as viewed in a main scanning direction. In Embodiment 2, a double-sided adhesive tape 21 is provided between the board 2 and the cover 5. The double-sided adhesive tape 21 is used for attaching the cover 5 and the board 2 together. The board 2 includes dam boards 2a on the same side where the magnetoresistive effect element 1 is mounted on the board 2 so as to surround the magnetoresistive effect element 1. The region, including the magnetoresistive effect element 1, surrounded by the dam boards 2a may be resin molded when necessary. The height of the resin mold is the same as the height of the dam boards 2a.

In the step illustrated in FIG. 8, in the case of placing the cover 5 on the opening outer edges 4d of the enclosure 4, the cover 5 is placed on the enclosure 4 with the double-sided adhesive tape 21 in an pre-attached state to the cover 5 on the board 2 side. The cover 5 and the dam boards 2a on the board 2 attach together with the double-side adhesive tape 21. In the case that the region surrounded by the dam boards 2a is resin molded, the double-side adhesive tape 21 also causes the resin mold to attach to the cover 5 at the same time as the dam boards 2a.

As described above, the cover 5 and the board 2 mounted with the magnetoresistive effect element 1 in the magnetic sensor device of Embodiment 2 can be fixed more tightly together compared to that of Embodiment 1. Since the affixing of the double-sided adhesive 21 to the cover 5 is performed before the adhesive 11 is applied to the step portions 4b, the board 2-and-cover 5 attachment step is unaffected.

### Embodiment 3

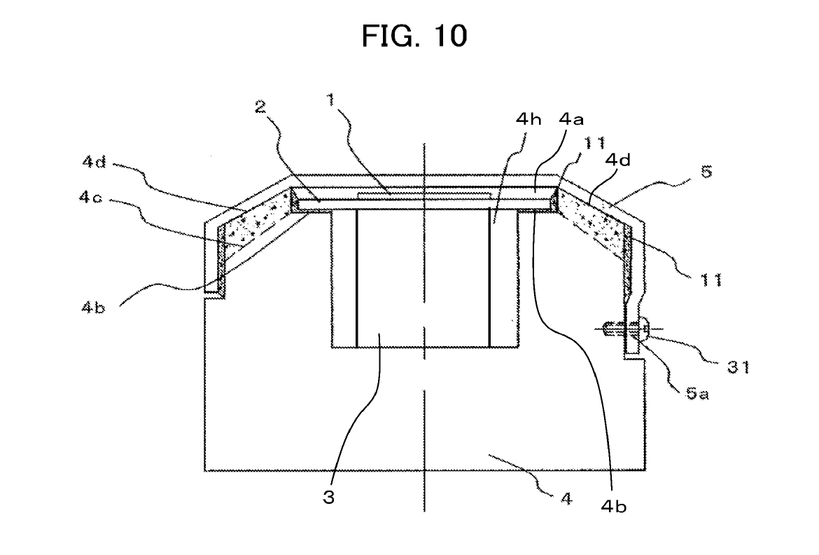

FIG. 10 is a cross-sectional view of a magnetic sensor device of Embodiment 3 of the present disclosure as viewed in a main scanning direction. The magnetic sensor device of Embodiment 3 includes a screw 31 to fix the cover 5 to the enclosure 4. The screw 31 is used for fixing the cover 5 to the enclosure 4. The cover 5 has a terminal hole 5a through which the screw 31 is driven. At the position of the terminal hole 5a when the cover 5 is in a placed state on the enclosure 4, the enclosure 4 has a female thread into which the screw 31 is screwed.

In the step illustrated in FIG. 8, when the cover 5 is placed on the opening outer edges 4d of the enclosure 4, the screw 31 is passed through the terminal hole 5a of the cover 5 and fixed to the female thread formed in the enclosure 4. If the enclosure 4 is metal, the enclosure 4 and the cover 5 are connected electrically together with the screw 31. Even if the enclosure 4 is not made of metal, a junction terminal may be used to achieve a ground connection between the cover 5 and another part.

As described above, the magnetic sensor device in Embodiment 3 of the present disclosure enables the cover 5 to be electrically connected to the ground.

The foregoing describes some example embodiments for explanatory purposes. Although the foregoing discussion has presented specific embodiments, persons skilled in the art will recognize that changes may be made in form and detail without departing from the broader spirit and scope of the invention. Accordingly, the specification and drawings are to be regarded in an illustrative rather than a restrictive sense. This detailed description, therefore, is not to be taken in a limiting sense, and the scope of the invention is defined only by the included claims, along with the full range of equivalents to which such claims are entitled.

This application claims the benefit of Japanese Patent Application No. 2014-151844 filed on Jul. 25, 2014, the entire disclosure of which is incorporated herein by reference.

### REFERENCE SIGNS LIST

1 Magnetoresistive effect element
2 Board
2a Dam board
3 Magnet
4 Enclosure
4a Opening
4b Step portion
4c Groove
4d Opening outer edge
4g Side wall
4h Housing portion
5 Cover
5a Terminal hole
6 To-be-detected object
7 Conveyance direction
11 Adhesive
21 Double-sided adhesive tape
31 Screw

1. A magnetic sensor device, comprising:
a board mounted with a magnetoresistive effect element;
a magnet to form a bias magnetic field for the magnetoresistive effect element;
an enclosure having an opening on a side of a conveyance path where a to-be-detected object containing a magnetic component is conveyed, and housing the magnet and the board, the magnetoresistive effect element being disposed on the side of the conveyance path; and
a cover to cover a plane on a side of the opening of the enclosure,
wherein the enclosure has step portions on which the board is supported in such a manner that the board lies across the opening on the side of the conveyance path and extends along a conveyance direction of the to-be-detected object, and has grooves, continuous with the step portions, extending from the opening to an outer surface of the enclosure on a side of the conveyance direction.

2. The magnetic sensor device according to claim 1, wherein a surface of the enclosure contacting the cover on the side of the conveyance path slants away from the conveyance path, as the surface approaches the outer surface on the side of the conveyance direction.

3. The magnetic sensor device according to claim 2, wherein a bottom surface of the grooves slants away from the conveyance path, as the bottom surface approaches the outer surface of the enclosure in the conveyance direction from the opening.

4. The magnetic sensor device according to claim 1, wherein the board and the cover are fixed to the enclosure with an adhesive.

5. The magnetic sensor device according to claim 4, wherein
the cover is fixed to the enclosure on opening outer edges formed on the enclosure along a direction orthogonal to the conveyance direction, and
the grooves are indentations along the conveyance direction on the opening outer edges of the enclosure.

6. The magnetic sensor device according to claim 4, wherein the adhesive is interposed between the cover and the grooves.

7. The magnetic sensor device according to claim 4, wherein the adhesive of the grooves and the step portions is continuous.

8. A magnetic sensor device manufacturing method comprising:
an adhesive application step for applying an adhesive onto step portions and grooves of an enclosure, wherein (i) the enclosure has an opening on a side of a conveyance path where a to-be-detected object containing a magnetic component is conveyed and the enclosure is formed so as to house (ia) a board mounted with a magnetoresistive effect element disposed on a side of the conveyance path and (ib) a magnet to form a bias magnetic field for the magnetoresistive effect element, (ii) the step portions support the board in such a manner that the board lies across the opening on the side of the conveyance path and extends along a conveyance direction of the to-be-detected object, and (iii) the grooves, continuous with the step portions, extend from the opening to an outer surface of the enclosure on a side of the conveyance direction;
a board placement step for placing the board on the step portions such that the board lies across the opening and extends along the conveyance direction of the to-be-detected object;
a cover placement step for placing a cover on a surface of the opening of the enclosure so as to cover the surface of the opening of the enclosure; and
an adhesive curing step for curing the adhesive after the board placement step and the cover placement step.
